(19) United States
(12) Patent Application Publication
(10) Pub. No.: US 2005/0204243 A1
(43) Pub. Date: Sep. 15, 2005

(54) Method and testing system for storage devices under test

(76) Inventors: Meihong Hu, Sunnyvale, CA (US); Keqi Yuan, Mountain View, CA (US)

Correspondence Address: Chiaoyun Kuo, 14851 Yucca Avenue, Irvine, CA, 92606, US

(21) Appl. No.: 10/895,454

(22) Filed: Jan. 21, 2004

(51) Int. Cl. G06F 11/00; G01R 31/28

(52) U.S. Cl. 714/742

(57) ABSTRACT

A testing system for storage devices under test (SDUT) is provided. The system comprises a storage device testing subsystem configured to send testing commands, to process feedback data from said SDUT, and to send power management commands to SDUT power supply systems, a bus, and an application designed to generate the testing commands and the power management commands, controlling the power modes of the SDUT power supply systems, are sent to the storage device testing subsystem.

### 1. RELATED APPLICATIONS

This application claims priority of U.S. Provisional Application Ser. No. 60/538,053 filed Jan. 21, 2004, which is incorporated herein by reference in its entirety.

### 2. BACKGROUND

2.1 Field of the Invention

The present invention relates to power control of a computer, and more particularly, to method and testing system for storage devices under test (SDUT).

2.2 Description of the Related Art

In a computer system, hard discs, floppy drives, CD drives, DVD drives and other storage devices are powered from the same power supply in the computer system. Computer operating system controls power saving of devices through power management. If the “Turn Off” button of the computer system is clicked, it will turn off the power supply for the computer system and all devices connecting to it. FIG. 1 depicts a common configuration of the computer system. The common setting will not allow user to turn on/off the particular power channel of a device while the whole system is still running.

All storage devices, before they go to market, have gone through all aspects of test phases. Some tests involve power on/off control. For examples, a hard disc should be in compliance with the IDE drive interface specification called ATA (Advanced Technology Attachment) interface. Several features set command execution in ATA/ATAPI (Attachment with Packet Interface) specification which requires power on and off cycle. In a reliability test of storage devices, one of the most commonly used methods is to test its features and performances with power on/off alternation. Another need for power on/off control is when a SDUT hangs up and it needs power off to perform a hardware reset.

The traditional test method used for SDUT power on/off control is to manually turn on/off power of the testing device if the device connects to an external power supply (FIG. 2), or the computer system is turned on/off to perform the testing device power on/off if it uses the same power supply as the computer (FIG. 1). Obviously, the methods mentioned above cannot be used for an automatic testing and is very inefficient. Therefore, a new method and testing system are invented to provide automatic power management and verify commands for SDUT.

The Method and Testing System for Storage Devices under Test will have the following benefits:
a. Safety: avoid damaging user's system hard drive because this testing system uses Add-on card to connect to computer system hard drive;
b. Reducing the number of times to reboot computer operating system: when the SDUT is hung, this testing system can power off/on the SDUT without rebooting computer operating system, because the SDUT is powered by present methods;
c. Easily switching SDUT: because the SDUT is powered by present methods, user can switch SDUT without shutting down operating system if the SDUT does not support Hot-plug or when Hot-plug feature is not ready yet;
d. Tests of power management features: these features can be thoroughly tested by the Method and Testing System for Storage Devices under Test.

The Advantage of the invention presented is simple and efficient. Because a computer system with various interface ports and switch power supply is already very popular, it is easy and fast to build a power management testing environment that can achieve automation control according to the Testing System and Methods for Storage Devices under Test. It especially benefits testing application under Windows environment. If the SDUT fail, with the special management of SDUT power supply, the whole testing system will not be affected. Because the power supply of the SDUT simulate the real world storage device power supply condition, various and flexible power on/off control methods can be achieved.

Also the power on/off commands can be sent by a script for automatic test, or by clicking “Power On/Power Off” buttons on the interface of an application program.

### 3. SUMMARY OF THE INVENTION

Accordingly, it is an object of the present invention to provide a testing system for SDUT which comprises a storage device testing subsystem configured to send testing commands, to process feedback data from said SDUT, and to send power management commands to SDUT power supply systems; a bus; and an application designed to generate the testing commands and the power management commands which are sent to the storage device testing subsystem. The power management commands control the power modes of the SDUT power supply systems.

Specifically, in one embodiment of the present invention, the storage device testing subsystem includes a computer system for sending testing commands to SDUT, receiving feedback data from SDUT and generating the power management command to control power modes of the one or more SDUT power supply systems.

In the present embodiment, the storage device testing subsystem also includes a PCI Add-on Card which connects computer system hard disk and other non-testing storage devices to a computer motherboard.

In the present embodiment, the storage device testing subsystem is designed to test the storage device features including but not limited to Advanced Technology Attachment (ATA) commands and Advanced Technology Attachment Packet Interface (ATAPI) commands.

In one embodiment, the bus will pass the power management commands to SDUT power supply. In one embodiment, the application is an application program which generates testing commands, processes feedback data, and issues power management commands.

In one embodiment, the power management includes Power-On command and Power-Off command. The Power-On command is an assertion to a SDUT power supply subsystem to switch to a power on mode. The Power-Off command is an assertion to a testing device power supply subsystem to switch to a power off mode.

### 4. BRIEF DESCRIPTION OF THE DRAWINGS

FIG. 1 is a simplified power connection view of storage devices in a computer system.

FIG. 2 is a view showing embodiment of using parallel port to control power supply of SDUT according to present invention.

FIG. 3 is a view showing a method through USB interface to achieve power switch control according to present invention.

FIG. 4 is a block diagram showing a constitution of using serial port interface means of the present invention.

FIG. 5 is a view showing embodiment of another constitution of inside solution implement of present invention.

FIG. 6 is a block diagram showing the testing system configuration.

### 5. DETAILED DESCRIPTION OF THE INVENTION

In general, the present disclosure describes a testing system and methods for SDUT in computer environment. For easier understanding, specific embodiments of present invention are shown in the drawings. However, the present invention is not limited to the example embodiments describe below.

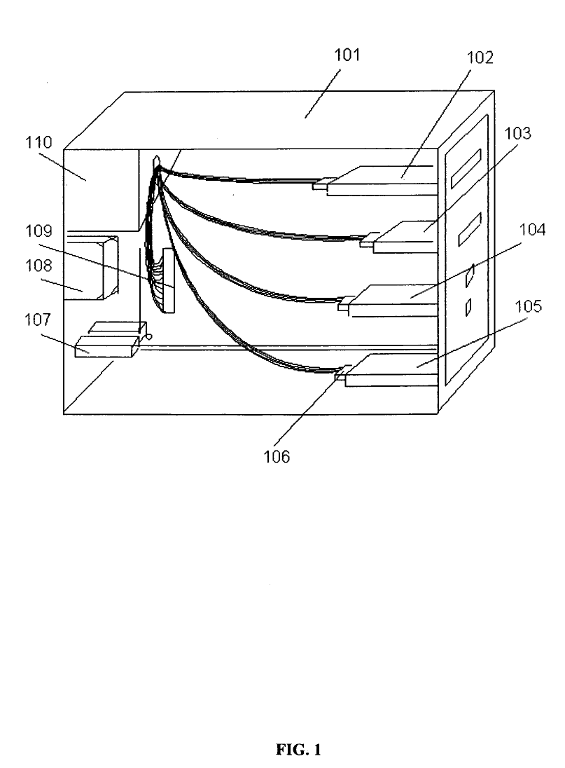

FIG. 1 shows a common computer system. The power cables of system hard disc 104, SDUT 105, CD/DVD/CDRW drive 102 and floppy drive 103 are all connected to a computer system power supply 110, which provide power for motherboard and its peripheral devices via different power cords. Current computer system can generate a power control signal to PS_ON control pin on computer system power supply, which will control power on/off to the whole computer system.

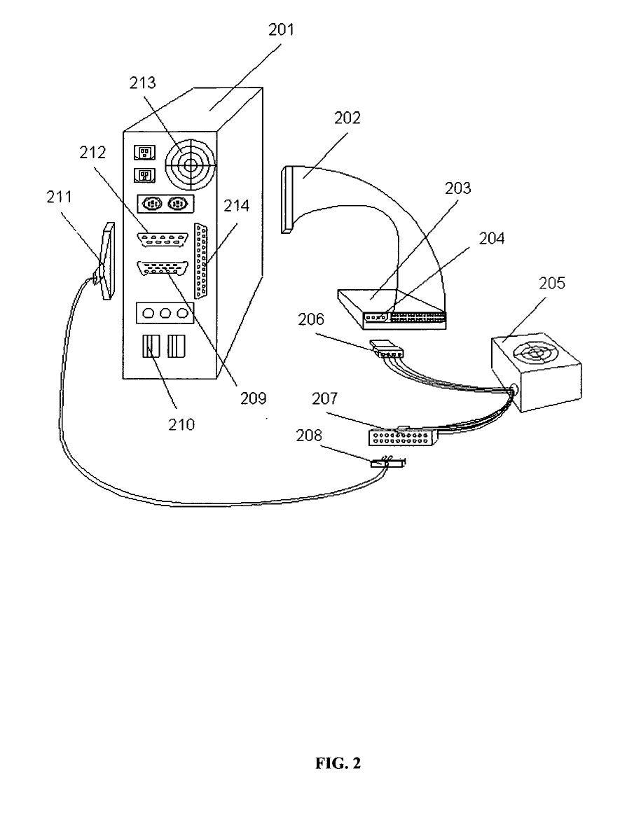

FIG. 2 depicts one of the solutions to provide an external power supply for SDUT with example embodiments of present invention. SDUT 203 is moved out from the computer and powered by an external power supply 205. Control connector 207 of the external power supply 205 is connected to computer system parallel port 214 via a parallel cable 211 in order to communicate with the computer system. An IDE cable 202 connects SDUT 203 and IDE channel in computer system. In this configuration the computer system makes specific power switch control for SDUT 203 by sending out control signal to turn on/off the external power supply 205 through parallel port 214.

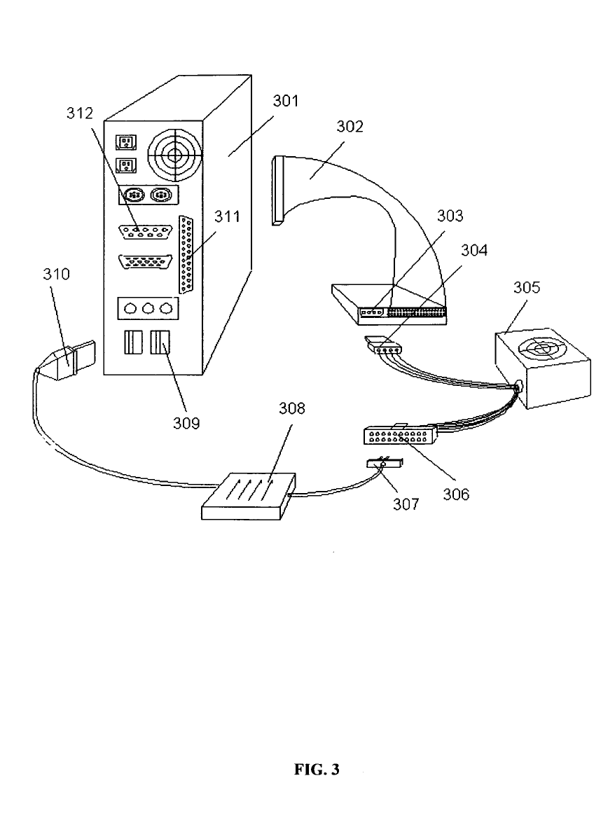

FIG. 3 depicts another method of power management through Universal Serial Bus (USB) port. USB has been used widely because of its convenience. An apparatus 308 of present invention is added. One of the apparatus terminals is connected to computer system via a USB cable 310. The other connector 307 is connected to the control connector 306 of the external power supply 305. The apparatus 308 is designed to convert control signals to 0 Volt and +5 Volts respectively. The power supply of SDUT is controlled by these two signals.

Other connections are remained the same as FIG. 2.

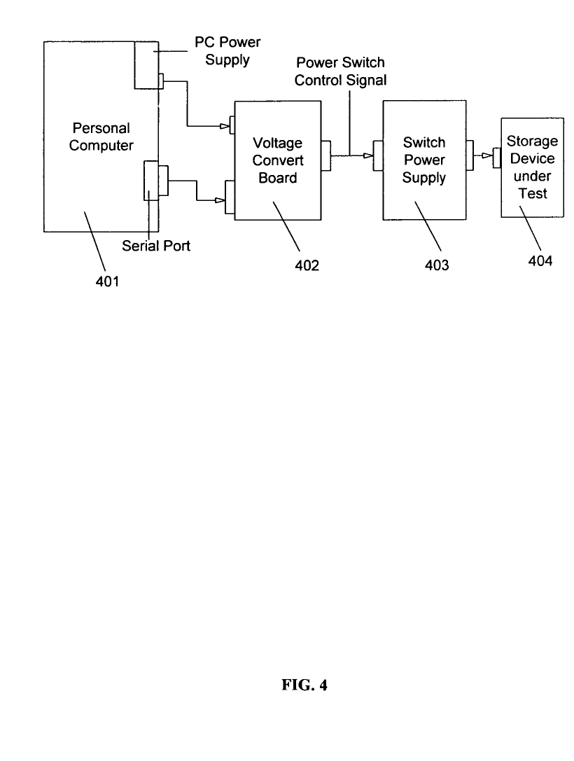

FIG. 4 is a block diagram that describes the method of present invention using serial port control. As is described in FIG. 3, an apparatus need to be added based on FIG. 2 configuration. The Voltage Convert Board 402 shown in FIG. 4 is a similar device as apparatus 308 in FIG. 3 but with different circuitry. Furthermore, the Voltage Convert Board 402 needs to get power supply from the computer system. It is different from the apparatuses of the parallel port and USB port, which can get power supply from their ports.

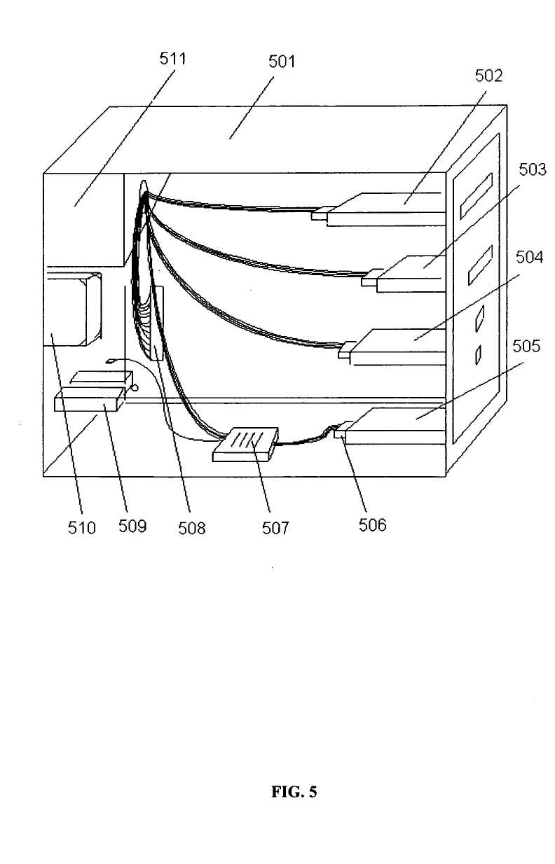

FIG. 5 shows an enhanced method of present invention. The configuration in FIG. 5 employs an apparatus 507 as a switch device working with parallel port to control signals.

The power provided by the computer system power supply for SDUT 505 is controlled by computer system port signals. Device of signal control also can come from USB or serial port. It depends on what kind of control channel is selected. The advantages of the method described here are two folds: 1. the user can easily integrate all devices to a computer system; 2. the implement cost is greatly reduced.

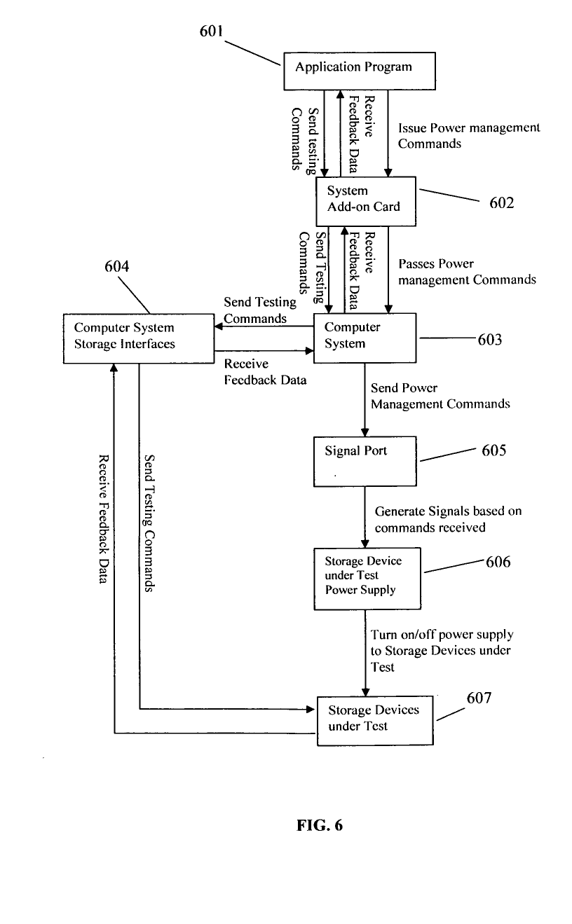

FIG. 6 displays a configuration of the Testing System. Application Program 601 generates and sends testing commands to System Add-on Card 602, processes feedback data sent from System Add-on Card 602, and issues power management commands to System Add-on Card 602. System Add-on Card 602 receives testing commands and power management commands from Application Program 601 and passes the commands to Computer System 603. It also receives feedback data from Computer System 603 and passes the data back to Application Program 601. Computer System 603 processes all the commands from System Add-on Card 602 and feedback data from Computer System Storage Interface 604. If the commands are testing commands, they are sent to Computer System Storage Interface 604, otherwise they are sent to Signal Port 605. Computer System Storage Interfaces 604 connects to SDUT 607 with signal cables. Computer System Storage Interfaces 604 passes testing commands to SDUT 607 and feedback data to Computer System 603. Signal Port 605 receives power management commands from Computer System 603 and generates signals to SDUT Power Supply 606. SDUT Power Supply 606 supplies power to SDUT 607 and processes signals from Signal Port 605.

1. A testing system for storage device under test (SDUT), comprising:
a storage device testing subsystem configured to send testing commands, to process feedback data from said SDUT, and to send power management commands to SDUT power supply systems;
a bus; and
an application designed to generate said testing commands and said power management commands which are sent to said storage device testing subsystem.

2. The testing system of claim 1, wherein
said power management commands control power modes of said SDUT power supply systems.

3. The testing system of claim 1, wherein
said storage device testing subsystem is a computer for sending said testing commands to said SDUT, receiving feedback data from said SDUT, and generating said power management commands to control power modes of said SDUT power supply systems.

4. The testing system of claim 1, wherein
said storage device testing subsystem is a PCI Add-on Card which connects system hard disk and other non-testing storage devices to a computer motherboard.
